(19) United States
(12) Patent Application Publication
(10) Pub. No.: US 2006/0041926 A1
(43) Pub. Date: Feb. 23, 2006

(54) Voice control of multimedia content

(75) Inventors: Anthony F. Istvan, Snoqualmie, WA (US); Korina J.B. Stark, Seattle, WA (US); Robin Budd, Seattle, WA (US)

Correspondence Address: SEED INTELLECTUAL PROPERTY LAW GROUP PLLC, 701 FIFTH AVE, SUITE 6300, SEATTLE, WA, 98104-7092, US

(73) Assignee: Vulcan Inc., Seattle, WA (US)

(21) Appl. No.: 11/118,093

(22) Filed: Apr. 29, 2005

Related U.S. Application Data
(60) Provisional application No. 60/567,186, filed on Apr. 30, 2004.

(51) Int. Cl. H04N 5/445; H04R 3/00; H03G 3/20; H04N 7/173

(52) U.S. Cl. 725/133; 725/44; 725/45; 381/110

(57) ABSTRACT

Techniques are described for managing various types of content in various ways, such as based on voice commands or other voice-based control instructions provided by a user. In some situations, at least some of the content being managed includes content of a variety of types, such as music and other audio information, photos, images, non-television video information, videogames, Internet Web pages and other data, etc., which may be managed via the voice controls in a variety of ways, such as to allow a user to locate and identify content of potential interest, to schedule recordings of selected content, to manage previously recorded content (e.g., to play or delete the content), to control live television, etc. This abstract is provided to comply with rules requiring it, and is submitted with the intention that it will not be used to interpret or limit the scope or meaning of the claims.

### CROSS REFERENCE TO RELATED APPLICATIONS

This application claims the benefit of provisional U.S. patent application Ser. No. 60/567,186, filed Apr. 30, 2004, and entitled “Voice-Controlled Natural Language Navigation Of Multimedia Programming Information,” which is hereby incorporated by reference in its entirety.

This application is also related to U.S. patent application Ser. No. ______ (Attorney Docket # 931086.414), filed concurrently and entitled “Voice Control Of Television-Related Information,” which is hereby incorporated by reference in its entirety.

### TECHNICAL FIELD

The present invention relates to techniques for navigating and controlling content via voice control, such as to manage television-related and other content via voice commands.

### BACKGROUND

In the current world of television, movies, and related media systems, many consumers receive television programming-related content via broadcast over a cable network to a television or similar display, with the content often received via a set-top box (“STB”) from the cable network that controls display of particular television (or “TV”) programs from among a large number of available television channels, while other consumers may similarly receive television programming-related content in other manners (e.g., via satellite transmissions, broadcasts over airwaves, over packet-switched computer networks, etc.). In addition, enhanced television programming services and capabilities are increasingly available to consumers, such as the ability to receive television programming-related content that is delivered “on demand” using Video on Demand (“VOD”) technologies (e.g., based on a pay-per-view business model) and/or various interactive TV capabilities. Consumers generally subscribe to services offered by a cable network “head-end” or other similar content distribution facility to obtain particular content, which in some situations may include interactive content and Internet content.

Consumers of content are also increasingly using a variety of devices to record and control viewing of content, such as via digital video recorders (“DVRs”) that can record television-related content for later playback and/or can temporarily store recent and current content to allow functionality such as pausing or rewinding live television. A DVR may also be known as a personal video recorder (“PVR”), hard disk recorder (“HDR”), personal video station (“PVS”), or a personal television receiver (“PTR”). DVRs may in some situations be integrated into a set-top box, such as with Digeo's MOXI™ device, while in other situations may be a separate component connected to an STB and/or television. In addition, electronic programming guide (“EPG”) information is often made available to aid consumers in selecting a desired program to currently view and/or to schedule for delayed viewing. Using EPG information and a DVR, a consumer can cause a desired program to be recorded and can then view the program at a more convenient time or location.

As the number and complexity of media-related devices used in home and other environments increase, however, it becomes increasingly difficult to control the devices in an effective manner. As one example, the proliferation in a home or other environment of large numbers of remote control devices that are each specific to a single media device creates well-documented problems, including difficulty in locating the correct remote control for a desired function as well as difficulty in learning how to effectively operate the multiple remote controls. While so-called “universal” remote control devices may provide at least a limited reduction in the number of remote control devices, such universal remote control devices typically have their own problems, including significant complexity in configuration and use. Furthermore, remote control devices typically have other problems, such as by offering only limited functionality (e.g., because the number of buttons and other controls on the remote control device are limited) and/or by having highly complex operations (e.g., in an attempt to provide greater functionality using only a limited number of buttons and controls). Moreover, the usefulness of remote control devices is also limited because the available functions are typically simple and non-customizable—for example, a user cannot enter a single command to move up 11 channels or to move to the next news channel (assuming that the next news channel is not adjacent to the current channel). In addition, many media devices increasingly provide functionality and information via on-screen menu interfaces displayed to the user (e.g., on the television), and use of remote control devices to navigate and interact with such on-screen menus can be extremely difficult—for example, if a user wants to enter alphanumeric data (e.g., an actor's name or a movie title) using a typical numerical keypad on a remote control device (or even a more extensive alphanumeric keypad if available), it is difficult and time-consuming.

Therefore, as the amount of content and number of content presentation devices continually grow, it is becoming increasingly difficult for consumers to effectively navigate and control the presentation of desired content. Thus, it would be beneficial to provide additional capabilities to consumers to allow them to more effectively perform such navigation and control of content and/or devices of interest.

### BRIEF DESCRIPTION OF THE DRAWINGS

FIG. 1 is a network diagram illustrating an example of a voice-controlled television content presentation system.

FIGS. 2A-2H illustrate examples of operation of a user interface for a voice-controlled multimedia system.

FIG. 3 is a block diagram illustrating an embodiment of a computing device for providing a voice-controlled content presentation system.

FIG. 4 is a network diagram illustrating an example of a voice-controlled multimedia content presentation system.

FIG. 5 is a flow diagram of an embodiment of a Voice Command Processing routine.

### DETAILED DESCRIPTION

Techniques are described below for managing various types of content in various ways, such as based on voice commands or other voice-based control instructions provided by a user. In some embodiments, at least some of the content being managed includes television programming-related content. In such embodiments, the television programming-related content can then be managed via the voice controls in a variety of ways, such as to allow a user to locate and identify content of potential interest, to schedule recordings of selected content, to manage previously recorded content (e.g., to play or delete the content), to control live television, etc. In addition, the voice controls can further be used in at least some embodiments to manage various other types of contents and perform various other types of content management functions, as described in greater detail below.

For illustrative purposes, some embodiments are described below in which specific types of content are managed in specific ways via specific example embodiments of voice commands and/or an accompanying example graphical user interface (“GUI”). However, the inventive techniques can be used in a wide variety of other situations, and that the invention is not limited to the specific exemplary details discussed. More generally, as used herein, “content” generally includes television programs, movies and other video information (whether stored, such as in a file, or streamed), photos and other images, music and other audio information (whether stored or streamed), presentations, video/teleconferences, videogames, Internet Web pages and other data, and other similar video or audio content.

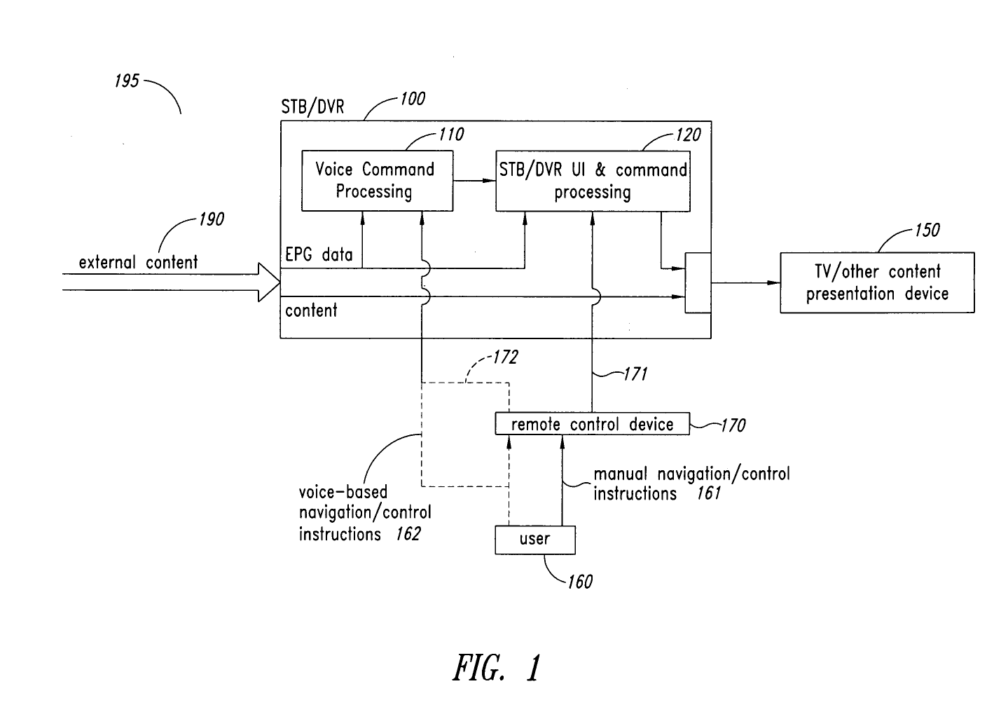

FIG. 1 is a network diagram illustrating an example of use of an embodiment of the described techniques in a home environment 195 for entertainment purposes, although the techniques could similarly be used in business or other non-home environments and for purposes other than entertainment. In this example, the home environment includes an STB and/or DVR 100 receiving external content 190 that is available to one or more users 160, such as television programming-related content for presentation on a television set display device or other content presentation device 150. Other types of audio and/or video content could similarly be received by the STB/DVR 100 or other media center device and presented to the user(s) on the television and/or optional other content presentation devices (e.g., other televisions, a stereo receiver, stand-alone speakers, the displays of various types of computing systems, etc.) in the environment.

In the illustrated embodiment, the STB/DVR contains a component 120 that provides a GUI and command processing functionality to users/viewers in a typical manner for an STB/DVR. For example, the component 120 may receive EPG metadata information from the external content that corresponds to available television programming, display at least some such EPG information to the user(s) via a GUI provided by the STB/DVR, receive instructions from the user related to the content, and output appropriate content to the TV 150 based on the instructions. The instructions received from the user may, for example, be sent as control signals 171 via wireless means from a remote control device 170, such as in response to corresponding manual instructions 161 that the user manually inputs to the remote control via its buttons or other controls (not shown) so as to effect various desired navigation and/or control functionality.

In addition, in the illustrated embodiment the STB/DVR further contains a Voice Command Processing (“VCP”) component or system 110 that receives and responds to voice commands from the user. In some embodiments, voice-based control instructions 162 from the user are provided directly from the user to the VCP system 110 (e.g., if the STB/DVR has a built-in microphone, not shown, to receive spoken commands from the user) to effect various navigation and control functionality. In other embodiments, voice-based instructions from the user may instead be initially provided to the remote control device, such as in a wireless manner (e.g., if the remote control includes a microphone) or via a wire/cable (e.g., from a head-mounted microphone of the user to the remote control device via a USB port on the device), and then forwarded 172 to the VCP system 110 from the remote control. After the VCP system 110 processes the voice-based control instructions (e.g., based on speech recognition processing, such as via natural language processing), the VCP system 110 in the illustrated embodiment then communicates corresponding information to the component 120 for processing. In some embodiments, the VCP system 110 may limit the information provided to the component 120 to those commands that the remote control device can transmit, while in the other embodiments a variety of additional types of information may be able to programmatically be communicated between the VCP system 110 and component 120. In addition, in some embodiments a user may have available only one of voice-based instruction capability and manual instruction capability with respect to the STB/DVR at a time, while in other embodiments a user can combine voice-based and manual instructions as desired to provide an enhanced interaction experience.

The VCP system 110 may be implemented in a variety of ways in various embodiments. For example, while the system 110 is executing on the STB/DVR device in the illustrated embodiment, in other embodiments some or all of the functionality of the system 110 could instead be provided in one or more other devices, such as a general-purpose computing system in the environment and/or the remote control device, with output information from those other devices then transmitted to the STB/DVR device. More generally, in at least some embodiments the functionality of the VCP system 110 may be implemented in a distributed manner such that processing and functionality is performed locally to the STB/DVR when possible, but is offloaded to a server (not shown, such as a server of a cable company supplying the external content) when additional information and/or computing capabilities are needed.

In addition, in some embodiments the VCP system 110 may include and/or use various executing software that provides natural language processing or other speech recognition capabilities (e.g., IBM ViaVoice software and/or VoiceBox software from VoiceBox Technologies), while in other embodiments some or all of the VCP system 110 could instead be embodied in hardware. In addition, the VCP system 110 may communicate with the component 120 in a variety of ways, such as programmatically (e.g., via a defined API of the component 120) or via transmitted commands that emulate those of the remote control device. Moreover, in some embodiments the VCP system 110 may retain and use various information about a current state of the component 120 (e.g., to determine subsets of commands that are allowed or otherwise applicable in the current state), while in other embodiments the VCP system 110 may instead merely pass along commands to the component 120 after they are received in voice format from the user and translated. Moreover, while not illustrated here, in some embodiments the component 120 may send a variety of information to the VCP system 110 (e.g., current state information). In addition, in embodiments in which the VCP system 110 is an application that generates its own GUI for the user (e.g., for display on the TV 150) and the STB/DVR further has a separate GUI corresponding to its functionality (e.g., also for display on the TV 150), the VCP system 110 and component 120 may in some embodiments interact such that the two GUIs function together (e.g., with access to one GUI available via a user-selectable control in the other GUI), while in other embodiments one or both of the GUIs may at times take over control of the display to the exclusion of the other GUIs.

Furthermore, and as discussed in greater detail below, the voice-based control instructions from the user can take a variety of forms and may be used in a variety of ways in various embodiments. For example, in addition to merely providing voice commands that correspond to or are mapped to controls of the remote control device, the user may in at least some embodiments provide a variety of additional information, such as voice annotations to be associated with pieces of content (e.g., to associate a permanent description with a photo, or to provide a temporary comment related to a recorded television program, such as to indicate to other users information about when/whether to view or delete the program), instructions to group multiple pieces of content together and to subsequently perform operations on the group (e.g., to group and schedule for recording several distinct television programs), etc.

While not illustrated in detail in FIG. 1, the example STB/DVR may also include a variety of hardware components, including a CPU, various I/O devices (e.g., a microphone, a computer-readable media drive, etc.), storage, memory, and one or more network connections or other inter-device communication capabilities (e.g., in a wireless manner, such as via an IR receiver or via Bluetooth functionality, etc.).

Moreover, the STB/DVR may in some embodiments take the form of one or more general-purpose computing systems that can execute various applications and provide various functionality beyond the capabilities of a traditional STB or DVR.

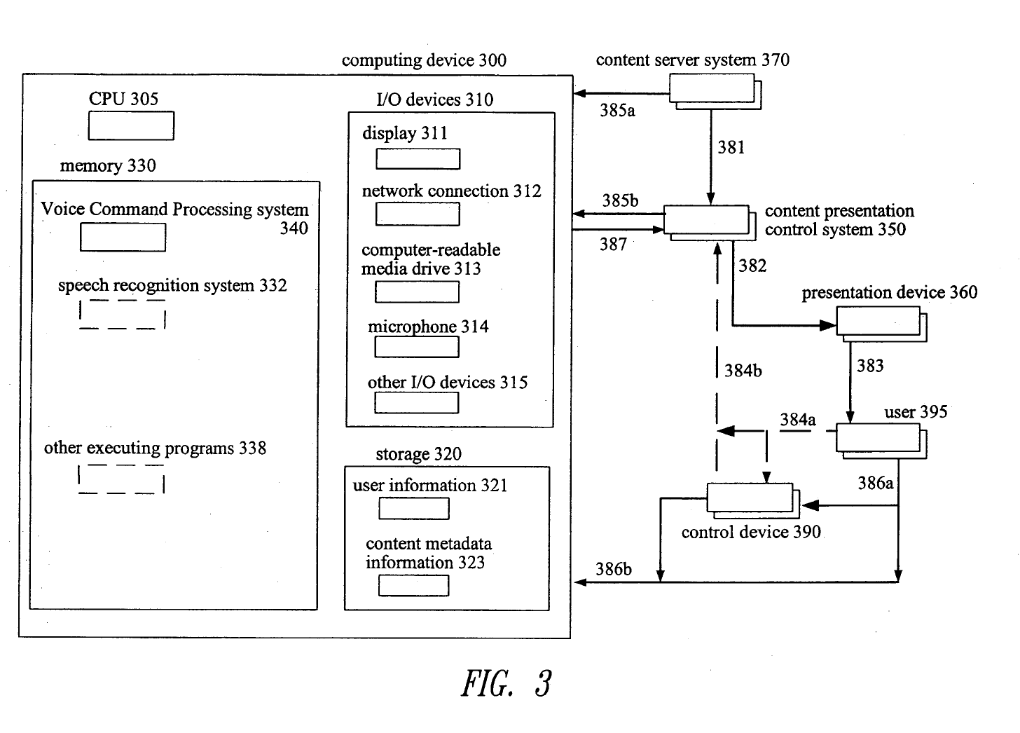

FIG. 3 illustrates a computing device 300 suitable for executing an embodiment of a voice-controlled content presentation system, as well as various other devices and systems with which the computing device 300 may interact. The computing device 300 includes a CPU 305, various input/output (“I/O”) devices 310, storage 320, and memory 330. In the illustrated embodiment, the I/O devices include a display 311, a network connection 312, a computer-readable media drive 313, a microphone 314, and other I/O devices 315.

An embodiment of a Voice Command Processing (“VCP”) system 340 is executing in memory, such as to provide voice-based content presentation functionality to one or more users 395. In some embodiments, the VCP system 340 may also interact with one or more optional speech recognition systems 332 executing in memory 330 in order to assist in the processing of voice-based control instructions, although in other embodiments such speech recognition capabilities may instead be provided via a remote computing system (e.g., accessible via a network) and/or may be incorporated within the VCP system 340. In a similar manner, in some embodiments one or more optional other executing programs 338 may similarly be executing in memory, such as to provide capabilities to the VCP system 340 or instead to provide other types of functionality.

In the illustrated embodiment, the VCP system 340 operates as part of an environment that may include various other devices and systems. For example, one or more content server systems 370 (e.g., remote systems, such as a cable company headend system, or local systems, such as a device that stores content on a local area network) provide 381 content of one or more types to one or more content presentation control systems 350 in the illustrated embodiment, such as to provide television programming-related content to one or more STB and/or DVR devices and/or to provide other types of multimedia content to one or more media center devices. The content presentation control systems then cause selected pieces of the content to be presented on one or more presentation devices 360 to one or more of the users 395, such as to transmit a selected television program to a television set display device for presentation and/or to direct that one or more pieces of other types of content (e.g., a digital music file) be provided to one or more other types of presentation devices (e.g., a stereo or a portable music player device). At least some of the actions of the content presentation control systems may optionally be initiated and/or controlled via instructions provided by one or more of the users to one or more of the content presentation control systems, such as instructions provided 384a directly to a content presentation control system by a user (e.g., via direct manual interaction with the content presentation control system) and/or instructions provided 384a to a content presentation control system by interactions by a user with one or more control devices 390 (e.g., a remote control device, a home automation control device, etc.) that transmit corresponding control signals to the content presentation control system, and with the directly provided instructions and/or transmitted instructions received 384b by the one or more content presentation control systems to which the instructions are directed.

In the illustrated embodiment, one or more of the users 395 may also interact with the computing device 300 in order to initiate and/or control actions of one or more of the content presentation control systems. Such voice-based control instructions may be provided 386a directly to the computing device 300 by a user (e.g., via spoken commands that are received by the microphone 314) and/or may be provided 386a via voice-based control instructions to one or more control devices 390 that transmit the voice-based control instructions and/or corresponding control signals (e.g., if the control device does some processing of the received voice-based control instructions) to the content presentation control system, with the directly provided instructions and/or transmitted instructions received 386b by the computing device 300. For example, when a control device is used to communicate with the computing device 300, the computing device may transmit information to the network connection 312 or to one or more other direct interface mechanisms (whether wireless or wired/cabled), such as for a local device to use Bluetooth or Wi-Fi, or for a remote device to use the Internet or a phone connection (e.g., via a cellphone connection or land line). In the illustrated embodiment, the computing device may also be accessed by users in various ways, such as via various I/O devices 310 if the users have physical access to the computing device. Alternatively, other users can use client computing systems (not shown) to directly access the computing device, such as remotely (e.g., via the World Wide Web or otherwise via the Internet).

After voice-based control instructions are received by the computing device 300, those instructions are provided in the illustrated embodiment to the VCP system 340, which analyzes the instructions in order to determine whether and how to respond to the instructions, such as to identify one or more corresponding content presentation control systems (if more than one is currently available) and/or one or more instructions to provide or operations to perform. Such analysis may in at least some embodiments use stored user information 321 (e.g., user preferences and/or user-specific speech recognition information, such as based on prior interactions with the user), stored content metadata information 323 (e.g., EPG metadata information for television programming and/or similar types of metadata for other types of content, such as received from a content server system whether directly 385a or via a content presentation control system 385b), and/or current state information (not shown) for the computing device 300 and/or one or more corresponding content presentation control systems.

When a valid voice-based control instruction is received, the VCP system 340 may optionally perform internal processing for itself and/or the computing device 300 if appropriate (e.g., if the control instruction is related to modifying operation or state of the VCP system 340 or computing device 300), and/or may send 387 one or more corresponding instructions and/or pieces of information to one or more corresponding content presentation control systems. Upon receipt of such instructions and/or information, such content presentation control systems may then respond in an appropriate manner, such as to modify 382 presentation of content on one or more presentation devices 360 (e.g., in a manner similar to or identical to the instruction if received 384b from the user without intervention of the VCP system 340).

While not illustrated here, a variety of other similar types of capabilities may be provided in other embodiments. For example, the computing device 300 may further store various types of content and use it in various ways, such as to present the content via one of the I/O devices 310 and/or to send the content to one or more content presentation control systems as appropriate (e.g., in response to a corresponding voice-based control instruction from a user). Such content may be acquired in various ways, such as from content server systems, from content presentation control systems, from other external computing systems (not shown), and/or from the user (e.g., via content provided by the user via the computer-readable media drive 313). In addition, the computing device may in some embodiments receive state and/or feedback information from the content presentation control systems, such as for use by the VCP system 340 and/or display to the users. In addition, the VCP system 340 may provide feedback and/or information (e.g., via a graphical or other user interface) to users in various ways, such as via one or more I/O devices 310 and/or by sending the information to the content presentation control systems for presentation via those systems or via one or more presentation devices.

Computing device 300 and the other illustrated devices and systems are merely illustrative and are not intended to limit the scope of the present invention. Computing device 300 may instead be comprised of multiple interacting computing systems or devices, may be connected to other devices that are not illustrated (including via the World Wide Web or otherwise through the Internet or other network), or may be incorporated as part of one or more of the systems or devices 350, 360, 370 and 390. More generally, a computing system or device may comprise any combination of hardware or software that can interact and operate in the manners described, including (without limitation) desktop or other computers, network devices, PDAs, cellphones, cordless phones, devices with walkie-talkie and other push-to-talk capabilities, pagers, electronic organizers, Internet appliances, television-based systems (e.g., using set-top boxes and/or personal/digital video recorders), and various other consumer products that include appropriate inter-communication and computing capabilities. In addition, the functionality provided by the illustrated computing device 300 and other systems and devices may in some embodiments be combined in fewer systems/devices or distributed in additional systems/device. Similarly, in some embodiments some of the illustrated systems and devices may not be provided and/or other additional types of systems and devices may be available.

While various elements are illustrated as being stored in memory or on storage while being used, these elements or portions of them can be transferred between memory and other storage devices for purposes of memory management and data integrity. Alternatively, in other embodiments some or all of the software systems and/or components may execute in memory on another device and communicate with the illustrated computing device 300 via inter-computer communication. Some or all of the VCP system 340 and/or its data structures may also be stored (e.g., as software instructions or structured data) on a computer-readable medium, such as a hard disk, a memory, a computer network or other transmission medium, or a portable media article (e.g., a DVD or flash memory device) to be read by an appropriate drive or via an appropriate connection. Some or all of the VCP system 340 and/or its data structures may also be transmitted via generated data signals (e.g., by being encoded in a carrier wave or otherwise included as part of an analog or digital propagated signal) on a variety of computer-readable transmission mediums, including wireless-based and wired/cable-based mediums, and can take a variety of forms (e.g., as part of a single or multiplexed analog signal, or as multiple discrete digital packets or frames). Such computer program products may also take other forms in other embodiments. Accordingly, other computer system configurations may be used.

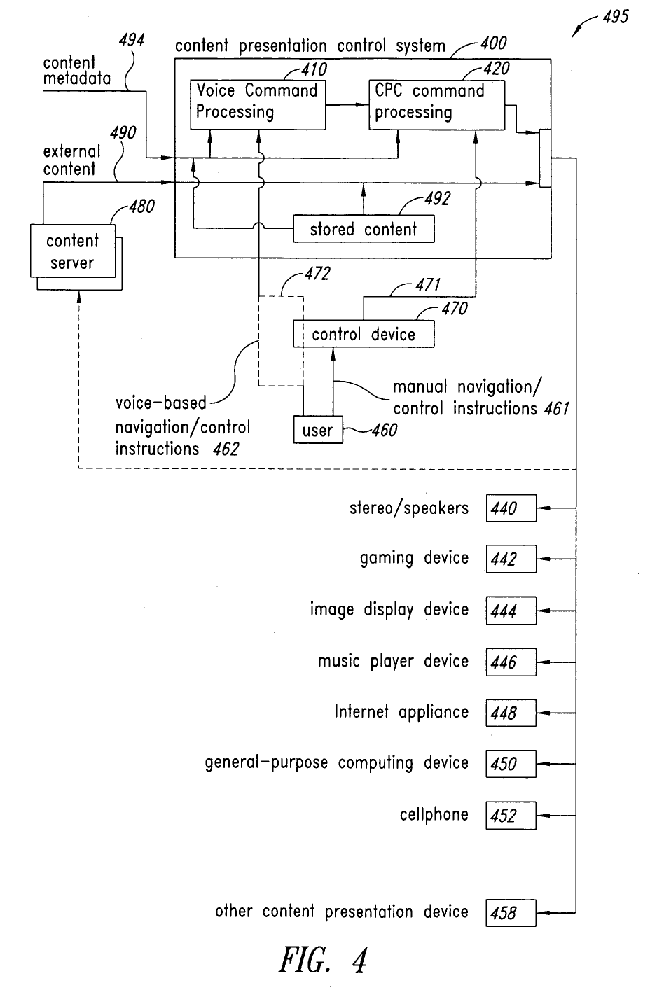

FIG. 4 is a network diagram illustrating an example of use of an embodiment of the described techniques in an environment 495 in a manner similar to that previously described with respect to FIG. 1, with some details related to similar aspects of the described operations for FIGS. 1 and 4 not included here for the sake of brevity. In this embodiment, an embodiment of the VCP system 410 executes as part of a content presentation control system 400, which receives external content 490 of one or more of a variety of types from one or more content servers 480 external to the system 400 (e.g., local and/or remote servers 480)—for example, the content may include music and other audio information, photos, images, non-television video information, videogames, Internet Web pages and other data, etc. In addition, the system 400 includes various metadata 494 for the content from one or more sources (e.g., from the content servers 480). Moreover, in this example embodiment the system 400 further includes stored content 492 and optionally corresponding metadata information for use in presentation.

The content presentation control system 400 may then direct content to be presented to one or more of various types of presentation devices, such as by directing audio information to one or more speakers 440 and/or to one or more music player devices 446 with storage capabilities, directing gaming-related executable content or related information to one or more gaming devices 442, directing image information to one or more image display devices 444, directing Internet-related information to one or more Internet appliance devices 448, directing audio and/or information to one or more cellphone devices 452 (e.g., smart phone devices), directing various types of information to one or more general-purpose computing devices 450, and/or directing various types of content to one or more other content presentation devices 458 as appropriate. Such content direction and other management by the control system 400 may be performed in various ways, such as by the content presentation control command processing component 420 in response to instructions received directly from one or more of the users 460 and/or in response to instructions from the VCP system 410 that are based on voice-based control instructions from one or more of the users 460. Such user instructions may be provided in various ways, such as via control signals 471 sent via wireless means from one or more control devices 470 (e.g., in response to corresponding manual instructions 461 that the user manually inputs to the control device via its buttons or other controls) and/or via voice-based control instructions 462 provided by a user directly to the control system 400 or provided to a control device for forwarding 472 to the control system 400.

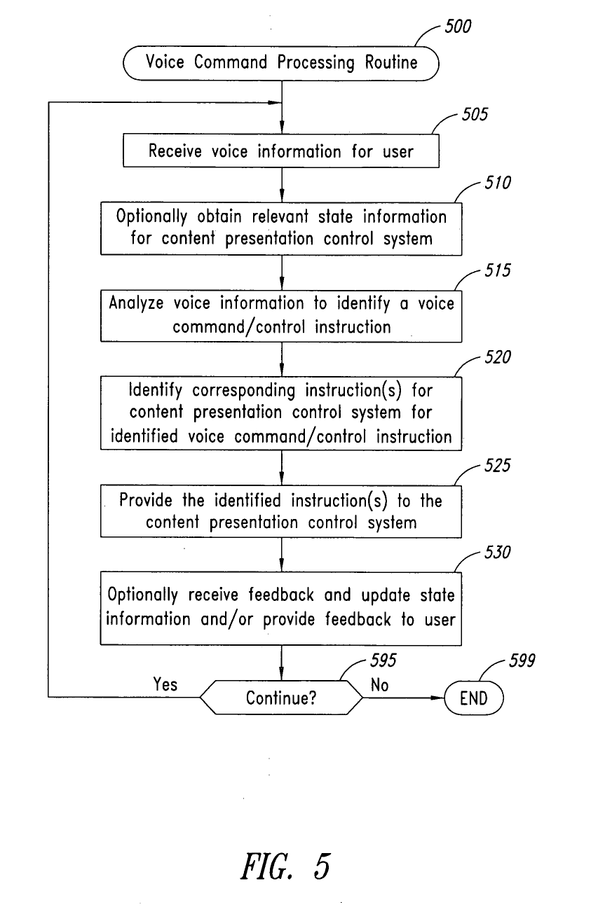

FIG. 5 illustrates a flow diagram of an embodiment of a Voice Command Processing routine. The routine may, for example, be provided by execution of an embodiment of the VCP system 110 of FIG. 1, the VCP system 340 of FIG. 3 and/or the VCP system 410 of FIG. 4. In the illustrated embodiment, the routine receives voice-based control instructions from one or more users and manages content accordingly, such as by interacting with one or more associated content presentation control systems. While not illustrated here, in some embodiments the routine may provide additional functionality to support interacting with multiple such systems or other devices and/or with multiple users, such as to allow association of the routine with a single system or device, to determine an appropriate corresponding system or device for each of some or all of the received voice-based control instructions, to retrieve and use user-specific information, etc.

In the illustrated embodiment, the routine begins at step 505, where voice information from a user is received. Such voice information may in some embodiments be received from a local user or from a remote user, and may in some embodiments include use of one or more control devices (e.g., a remote control device) by the user. In step 510, the routine then optionally retrieves relevant state information for the voice command processing routine and/or an associated content presentation control system, such as if the state information will be used to assist speech recognition of the voice information. In step 515, the received voice information is then analyzed to identify one or more voice commands or other voice-based control instructions, such as based on speech recognition processing.

In step 520, one or more corresponding instructions for an associated content presentation control system are identified based on the one or more voice commands or control instructions identified in step 515, and in step 525 the identified corresponding instructions are provided to the corresponding content presentation control system. In step 530, the routine optionally receives feedback information from the content presentation control system and uses that information to update the current state information for the content presentation control system and/or to provide feedback to the user. The routine then continues to step 595 to determine whether to continue. If so, the routine returns to step 505, and if not continues to step 599 and ends.

As previously noted, in some embodiments various types of non-television content may be managed in various ways. For example, in some embodiments at least some of the content being managed may include digital music content and other audio content, including digital music provided by a cable system and/or via satellite radio, digital music available via a download service, etc. In such embodiments, the music content can be managed via the voice controls in a variety of ways, such as to allow a user to locate and identify content of potential interest, to schedule recordings of selected content, to manage previously recorded content (e.g., to play or delete the content), to control live content, etc. Such digital music content and other audio content may be controlled via various types of content presentation control devices, such as a DVR and/or STB, a satellite or other radio receiver, a media center device, a home stereo system, a networked computing system, a portable digital music player device, etc. In addition, such digital music content and other audio content may be presented on various types of presentation devices, such as speakers, a home stereo system, a networked computing system, a portable digital music player device, etc.

In a similar manner, in some embodiments at least some of the content being managed may include photos and other images and/or video content, including digital information available via a download service. In such embodiments, the image and/or video content can be managed via the voice controls in a variety of ways, such as to allow a user to locate and identify content of potential interest, to schedule recordings of selected content, to manage previously recorded content (e.g., to play or delete the content), to control live content, etc. Such digital image and/or video content may be controlled via various types of content presentation control devices, such as a DVR and/or STB, a digital camera and/or camcorder, a media center device, a networked computing system, a portable digital photo/video player device, etc. In addition, such digital image and/or video content may be presented on various types of presentation devices, such as television, a networked computing system, a portable digital photo/video player device, a stand-alone image display device, etc.

The examples of types of content and corresponding types of associated devices are merely illustrative and are not intended to limit the scope of the present invention, as discussed above.

The following describes an embodiment of a VCP application that uses voice commands to enhance user experience when navigating or controlling content, such as television programming-related content. In this example embodiment, a user is able to use a remote control to manipulate in a typical manner an STB device (or similar device) that controls presentation of television programming on a television, but also is able to use voice commands to manipulate the device (e.g., an integrated STB/DVR device, such as Digeo's MOXI™ device). The voice commands can thus expand the capabilities of the remote control by allowing the user to find and browse media with natural language.

A. Example Capabilities

i. Provide audio/visual feedback to the user, such as to indicate the following:
It's listening
It can hear you
This is what it heard
It can/can't do it

ii. Have voice controls that replicate all remote control button functions

iii. Help
Display help/how to/user guide for speech functionality
Help should be accessible from anywhere.

iv. TV content control capabilities
Go to full screen
Channel tuning
   Go up/down a channel
   Go to a channel by number
   Go to a channel by name
Transport control
   Pause/play
   FF/Rew
   Jump to beginning
   Jump X minutes
   Jump to a specific time
      Live TV—go back to 8 pm/play from 7:30
      Recorded TV—go 23 minutes into it
Record a show/Record a series pass
   Interact with a modal dialog in full screen TV

v. STB/DVR menu
Bring up the menu
Jump to filters/lists in the menu
   Jump to sports/kids/movies, etc.
Shift the time in any/all channels
   What's on tonight
   What's on at 8
Find (not tune) a channel by name/number
Go to full screen TV (without tuning)
Tune a channel and go full screen
Play a recorded program
Record a show/record a series pass
   Interact with a modal dialog in the menu

vi. Search UI
Initiate a search
   Find/show me/are there any
Bring up the search screen with the last search still presented
   Last search
Clear the search criteria
   New search
Add successive criteria to further narrow the search (always an “and’)
   Cast/crew
   Title
   Keyword
   Genre
Swap time criteria (only one at a time)
   Channel (by name/call sign/affiliate or number)
   On now
   At 8
   Tomorrow night
Add other criteria
   HDTV
   First run (not a repeat)
Back out of criteria/searches
   E.g.—“back”, “go back”, “last search”
Save a search
Access and apply saved searches
Reorder/Sort the list
   Sort by what's on next
   Put in alphabetical order
Watch a program that's on now (from search UI)
Play a recorded program (from search UI)
Record a show/record a series pass (from search UI)
   Interact with a modal dialog in STB/DVR menu (from search UI)
Search results include recorded programs, recording programs, programs on now, programs in the future, and scheduled programs.
   Display appropriate recording icon beside and recorded, recording, or scheduled program.
   Update recording icon if the state of the program changes (e.g.—user requests/cancels a record event)
      B. Example Voice Commands

1. Voice Command Conventions

| | |
|---|---|
| “” | Double quotes contain voice commands, unless noted by a |
| | column heading. |
| [ ] | Square brackets enclose single or grouped optional items. |
| ( ) | Parentheses enclose items that may be grouped together, such as for |
| | preferred items. |
| \| | Pipes separate alternative items. |
| $ | Dollar signs prefix criteria. |

2. What's On

“What's on” commands are meant to display (but not act on) a show at the intersection of a channel and date/time. As before, either time or channel criteria may be assumed.

| Sample | |
|---|---|
| sentences | Voice Command |
| What's on? | (What's on \| What is on \| What on) |
| What's on at | (What's on \| What is on \| What on) [at] $Time |
| three? | |
| What's on | |
| tonight? | |
| What's on | (What's on \| What is on \| What on) channel |
| channel two? | $ChannelNumber |
| What's on | (What's on \| What is on \| What on) [the] $ChannelName |
| Nickelodeon? | |
| What's on the | |
| Disney | |
| Channel? | |
| What's on | (What's on \| What is on) channel $ChannelNumber [at] |
| channel three at | $Time |
| eight? | |
| What's on | (What's on \| What is on) [the] $ChannelName [at] $Time |
| ESPN tonight? | |

3. Go To

“Go to” a channel name or number just sends the channel number as if the end user had entered the channel number with the remote control. Therefore, if the user is in full-screen television, it will end up tuning the channel, and if the end user is in an STB/DVR menu with channels in the vertical axis, it will attempt to bring that channel number into center focus. By doing this it doesn't have to have knowledge of its current location. “Go to” also allows end users to go to specific locations in an STB/DVR menu, such as “Recorded TV”.

| Sample sentences | Voice Command |
|---|---|
| Go to channel six. | Go to channel $ChannelNumber |
| Go to channel sixteen | |
| Go to Nickelodeon | Go to [the] $ChannelName |
| Go to NBC | |
| Go to the Disney Channel | |
| Go to Recorded TV | Go to [my\|the] $MenuLocation |
| Go to my Photos | |
| Go to the Parental Controls | |

4. Tune To

“Tune to” goes to a channel full-screen. Because of this, it needs to ensure that the end user is watching full-screen TV.

| Sample sentences | Voice Command |
|---|---|
| Tune to channel six. | Tune to channel $ChannelNumber |
| Tune to channel sixteen | |
| Tune to Nickelodeon | Tune to [the] $ChannelName |
| Tune to NBC | |
| Tune to the Disney Channel | |

5. Search

a. New Searches

(Find | Are there| Search for) always start a new search. Therefore, if the user is not in the search interface, the system will “Go to” it for them, and then execute the search.

| Sample sentences | Voice Command |
|---|---|
| Find shows | (Find \| Are there \| Search for) [any \| a] (show \| shows \| |
| starring Jennifer | program \| programs \| movie \| movies) (with \| star \| |
| Aniston. | that star \| starring) $Cast |
| Are there any | |
| programs with | |
| Clint Eastwood? | |
| Find any movies | (Find \| Are there \| Search for) [any \| a] (show \| shows \| |
| by Robert | program \| programs \| movie \| movies) (by \| directed |
| Altman. | by) $Director |
| Find a show | (Find \| Are there \| Search for) [any \| a] (show \| shows \| |
| called Bonanza. | program \| programs \| movie \| movies) (called \| |
| | named \| titled) $Title |
| Are there any | (Find \| Are there \| Search for) [any \| a] (show \| shows \| |
| programs about | program \| programs \| movie \| movies) about [the] |
| monkeys? | $Keyword |
| Search for shows | |
| about the | |
| civil war. | |
| Find baseball | (Find \| Are there \| Search for) [any \| a \| an] $Genre |
| games. Find | [show \| shows \| program \| programs \| movie \| movies \| |
| docudramas. Find | game \| games] |
| an animated | |
| movie. | |

b. Multi-Keyed Searches

For voice command searches, the start of the command (Find |Are there| Search for) is combined with the criteria, such as via concatenation. $Cast, $Director, $Title, and $Keyword are all paired with a qualifier, such as “(with |starring) $Cast” or “(called |named) $Title”, but Genre does not have a qualifier. In search commands with multiple criteria, $Genre is usually the first to be mentioned. For example, “Are there any biographies about Churchill?” This is one way to create a multi-keyed search.

Another way is to ask successive questions to further narrow the list. For example, “Find shows with Tom Hanks”, and then “Which ones are romantic comedies?” followed by “Which ones star Meg Ryan?”. This may produce, for example, any instances of ‘Sleepless in Seattle’ and ‘You've Got Mail’ that come up in the next two weeks. In this example, new criteria are added to the existing criteria—starting a fresh search would use (Find | Are there | Search for).

As criteria are added, they are joined by “and” rather than “or” in this example embodiment. The reason for this is that the objective of adding criteria is to narrow the list.

| Sample sentences | Voice Command |
|---|---|
| Are there any | (Find \| Are there \| Search for) [any \| a \| an] $Genre |
| biographies | [show \| shows \| program \| programs \| movie \| |
| about Churchill? | movies \| game \| games] ((with \| star \| that star \| |
| | starring) $Cast \| (by \| directed by) $Director \| |
| | (called \| named \| titled) $Title \| about [the] |
| | $Keyword) |
| Which ones star | (Which \| Which is \| Which are \| Which ones \| Which |
| Meg Ryan? | ones are) ((with \| star \| that star \| starring) |
| | $Cast \| (by \| directed by) $Director \| (called \| |
| | named \| titled) $Title \| about [the] $Keyword) |
| Which are | (Which \| Which is \| Which are \| Which ones \| Which |
| comedies? | ones are) $Genre [show \| shows \| program \| |
| | programs \| movie \| movies \| game \| games] |
| Which are High | (Which \| Which is \| Which are \| Which ones \| Which |
| Def? | ones are) $Attribute |
| Which ones are | (Which \| Which is \| Which are \| Which ones \| Which |
| on tonight? | ones are) on $Time |
| Which are on | (Which \| Which is \| Which are \| Which ones \| Which |
| HBO? | ones are) on ([the] $ChannelName \| channel |
| | $ChannelNumber) |

c. Sorting

Users can change the sort criteria, as well as the direction (ascending or descending) in some embodiments, although it is easy to move between the bottom and top of the list.

| Sample sentences | Voice Command |
|---|---|
| Sort by time. | (Sort by \| List by) $SortOrder |
| List by channel. | |
| Sort by title. | |

6. Help

In this example embodiment, help brings up a single screen's worth of help text that supplies the end user with basic information: how to operate the microphone, and some basic commands to try.

| Sample sentences | Voice Command |
|---|---|
| Help | Help |

7. Remote Control Buttons

In this example embodiment, the functionality of the remote control is duplicated, including basic commands such as the directional arrows and the transport controls. The functionality of these commands in this example embodiment matches exactly their remote control button counterparts, and thus they are not discussed in detail below.

| Sample sentences | Voice Command |
|---|---|
| OK button | $Button button |

8. Virtual Buttons

| Sample sentences | Voice Command |
|---|---|
| Select Close | Select $VirtualButton |

9. Skip

This is the ultimate transport control, and is primarily useful when watching full-screen TV. Skipping a relative amount of time forward or back is based on the current point in the buffer; jumping to an absolute time goes to a specific location in either the live buffer or the recording.

| Sample sentences | Voice Command |
|---|---|
| Skip three minutes | Skip [ahead \| forward] $Number |
| | (minutes\|seconds) |
| Skip back two minutes | Skip back $Number |
| | (minutes\|seconds) |
| Skip to 8 thirty (e.g., in | Skip to $AbsoluteTime |
| live buffer) | |
| Skip to 30 minutes (e.g., in | Skip to $Number (minutes\|seconds) |
| recorded buffers) | |

10. Change User

The “Change User” allows the user to switch to different voice training profiles in this example embodiment, such as by cycling through the user profiles each time “Change User” is recognized. The current loaded user profile may also be identified to the user in various ways in at least some embodiments (e.g., by calling TRD_CmdSendHeardStr and sending the user name when successfully connected).

Voice Command

Change User

C. Example Criteria

Criteria can be used with searches and with commands, as commands consist of keywords and criteria—the keywords identify the command and criteria are the variables. For example, in the command “Go to channel seven”, “Go to channel” are keywords that tell the system that the end user wants to go to a channel, and “seven” indicates which channel to go to.

1. $AbsoluteTime

Works Like $Date:

(hour) (minute)
Live programs may only accept times that exist within the buffer, and recorded programs may only accept times that are the length of the recording or less.

2. $Attribute

Fields to Search for $Attribute:

Sc_flags:tf_repeat

Sc_flags:tf_hdTV

| Spoken Criteria | Value |
|---|---|
| HD | HDTV |
| High Def | |
| In High Def | |
| High Definition | |
| In High Definition | |
| A repeat | IsRepeat |
| Repeats | |
| Not a repeat | IsNotRepeat |
| Aren't repeats | |

3. $Button

| Default Button Command | Alternatives |
|---|---|
| zero button | number zero |
| one button | number one |
| two button | number two |
| three button | number three |
| four button | number four |
| five button | number five |
| six button | number six |
| seven button | number seven |
| eight button | number eight |
| nine button | number nine |
| (star\|asterisk) button | |
| clear button | |
| enter button | |
| (forward\|fast forward) button | |
| (info\|information) button | |
| jump button | |
| next button | |
| OK button | |
| Pause button | |
| Play button | |
| Record button | |
| Replay button | |
| Rewind button | |
| Stop button | |
| Zoom button | |
| (Channel up\|page up) button | (channel up \| page |
| | up) |
| (Channel down\|page down) button | (channel down \| |
| | page down) |
| Skip button | refer to Skip |
| | command |
| back button | go back\|back button |
| down button | go down |
| left button | go left |
| right button | go right |
| up button | go up |
| guide button | Go to [the] |
| | $MenuLocation |
| (live TV\|live) button | Go to [the] |
| | $MenuLocation |
| (<STB device name> \| <STB device name> | Go to [the] |
| menu \| menu) button | $MenuLocation |
| ticker button | Go to [the] |
| | $MenuLocation |
| In this example embodiment, | |
| no voice command (IR only) | |
| In this example embodiment, | |
| no voice command (IR only) | |
| In this example embodiment, | |
| no voice command (IR only) | |
| In this example embodiment, | |
| no voice command (IR only) | |

4. $Cast

Fields to Search for $Cast:

Where the Value of cc_role is “Actor”, Search:

Cc_first
Cc_last

5. $ChannelNumber

Any spoken number may be accepted and sent to the STB/DVR as the value.

6. $ChannelName

The following example list is representative and serves two purposes. First, it is the subset of channels to be used for searching in this example. Second, it is the list of channels in this example whose name may be recognized with a voice command.

| ID | Channel Name | Call sign | # | Tier | In? | Spoken Name | Name 2 |
|---|---|---|---|---|---|---|---|
| 10035 | A & E Network | ARTS | 23 | 2 | y | A and E | |
| 10093 | ABC Family | FAM | 65 | 2 | y | ABC Family | |
| 10021 | AMC | AMC | 60 | 2 | y | AMC | |
| 16331 | Animal Planet | ANIMAL | 69 | 2 | y | Animal Planet | |
| 18332 | BBC America | BBCA | 341 | 2 | y | BBC America | |
| 14897 | BET on Jazz: The Cable Jazz | BETJAZZ | 340 | 2 | y | BET Jazz | |
| | Channel | | | | | | |
| 10051 | Black Entertainment Television | BET | 22 | 1 | y | Black Entertainment | BET |
| | | | | | | Television | |
| 14755 | Bloomberg Television | BLOOM | 323 | 2 | y | Bloomberg Television | Bloomberg |
| 21883 | Boomerang | BOOM | 354 | 2 | y | Boomerang | |
| 10057 | Bravo | BRAVO | 40 | 2 | y | Bravo | |
| 10142 | Cable News Network | CNN | 29 | 2 | y | Cable News Network | CNN |
| 10161 | Cable Satellite Public Affairs | CSPAN | 47 | 1 | y | Cable Satellite Public Affairs | CSPAN |
| | Network | | | | | Network | |
| 10162 | Cable Satellite Public Affairs | CSPAN2 | 48 | 1 | y | Cable Satellite Public Affairs | CSPAN 2 |
| | Network 2 | | | | | Network 2 | |
| 12131 | Cartoon Network | TOON | 64 | 2 | y | Cartoon Network | |
| 10120 | CineMAX | MAX | 56 | 3 | y | CineMAX | |
| 10139 | CNBC | CNBC | 43 | 2 | y | CNBC | |
| 16051 | CNN Financial News | CNNFN | 320 | 2 | y | CNN Financial News | |
| 10145 | CNN Headline News | CNNH | 33 | 2 | y | CNN Headline News | |
| 10149 | Comedy Central | COMEDY | 39 | 2 | y | Comedy Central | |
| 10138 | Country Music Television | CMTV | 58 | 2 | y | Country Music Television | CMT |
| 10153 | Court TV | COURT | 61 | 2 | y | Court TV | |
| 34668 | Cox New Orleans WDSU-DT | CXWDSU | 706 | 2 | y | Cox New Orleans WDSU- | Cox New |
| | | | | | | DT | Orleans |
| 31950 | Cox Sports Television | COXSPTV | 37 | 2 | y | Cox Sports Television | |
| 31046 | Discovery HD Theatre | DHD | 732 | 2 | y | Discovery HD Theatre | Discovery |
| | | | | | | | HD |
| 18327 | Discovery Health | DHC | 74 | 2 | y | Discovery Health | |
| 16618 | Discovery Kids Network | DCKIDS | 100 | 1 | y | Discovery Kids Network | Discovery |
| | | | | | | | Kids |
| 10171 | Disney Channel | DISN | 30 | 2 | y | Disney Channel | Disney |
| 18544 | Do-It-Yourself Network | DIY | 329 | 2 | y | Do-It-Yourself Network | DIY |
| 10989 | E! Entertainment Television | ETV | 44 | 2 | y | E! Entertainment Television | E |
| 10178 | ENCORE - Encore | ENCORE | 282 | 3 | y | ENCORE - Encore | Encore |
| 10179 | ESPN | ESPN | 35 | 2 | y | ESPN | |
| 12444 | ESPN2 | ESPN2 | 36 | 2 | y | ESPN2 | |
| 16485 | ESPNEWS | ESPNEWS | 326 | 2 | y | ESPNEWS | ESPN News |
| 32645 | ESPNHD | ESPNHD | 735 | 2 | y | ESPNHD | ESPN HD |
| 10183 | Eternal Word Television | EWTN | 46 | 1 | y | Eternal Word Television | Eternal Word |
| | Network | | | | | Network | |
| 30156 | Fine Living | FLIVING | 356 | 2 | y | Fine Living | |
| 10201 | Flix | FLIX | 307 | 3 | y | Flix | |
| 12574 | Food Network | FOOD | 67 | 2 | y | Food Network | FOOD TV |
| | . | | | | | | |
| | . | | | | | | |
| | . | | | | | | |

7. $Director

Where the Value of cc_role is “Director”, Search:

Cc_first
Cc_last

8. $Genre

Fields to Search for $Genre:

Ge_genre
biographies documentaries
docudramas westerns
comedies
sitcoms

soaps

| Spoken Criteria | Genre Values |
|---|---|
| (in addition to the Genre itself) | (Also, what you can say) |
| | Action |
| Adult | Adults only |
| | Adventure |
| | Aerobics |
| | Agriculture |
| | Animals |
| Animation | Animated |
| | Anime |
| Anthologies | Anthology |
| | Archery |
| Arts | Art |
| Arts and Crafts | Arts/crafts |
| | Auto |
| | Auto racing |
| | Aviation |
| | Awards |
| | Ballet |
| | Baseball |
| | Basketball |
| | Biathlon |
| | Bicycle |
| | Bicycle racing |
| | Billiards |
| Biographies | Biography |
| Boats | Boat |
| | Boat racing |
| | Bobsled |
| | Bodybuilding |
| | Bowling |
| | Boxing |
| Business\|Financial\|Business and Financial | Bus./financial |
| | Cheerleading |
| Children\|Children's\|Kids | Children |
| Children's Music | Children-music |
| Children's Special | Children-special |
| Children's Talk | Children-talk |
| . | |
| . | |
| . | |

1. $Keyword

Fields to Search for $Keyword:

Pr_title
Pr_desc_{—}0
Pr_epi_titie

2. $MenuLocation

Most of these menu locations are true destinations, and some can be achieved by sending a button press command.

| | | What it's called or |
|---|---|---|
| | | where it is in |
| Spoken Criteria | Criteria Type | this example |
| Find | $MenuLocation | Find and Record |
| Find and Record | | |
| Favorites | $MenuLocation | Favorite Channels |
| Favorite Channels | | |
| Take from $Button section | $Button | |
| Help | $MenuLocation | |
| Intro | $MenuLocation | Intro |
| Kids | $MenuLocation | Kids |
| Take from $Button section | $Button | |
| Take from $Button section | $Button | |
| Movies | $MenuLocation | Movies |
| Music | $MenuLocation | Music |
| News | $MenuLocation | News |
| Parental Controls | $MenuLocation | Settings: Parental Controls |
| Pay Per View | $MenuLocation | Pay Per View |
| Recorded TV | $MenuLocation | Recorded TV |
| Recorded Shows | | |
| Recordings | | |
| Search | $MenuLocation | Search UI |
| Series Options | $MenuLocation | Find and Record: Series |
| Series Manager | | Options |
| Series Organizer | | |
| Series Pass Options | | |
| Series Pass Manager | | |
| Series Pass Organizer | | |
| Settings | $MenuLocation | Settings |
| Sports | $MenuLocation | Sports |
| Take from $Button section | $Button | |

3. $Number

Any spoken number will be accepted and sent to the STB/DVR as the value.

4. $SortOrder

| Spoken | Field to Sort | Default Sort | |
|---|---|---|---|
| Criteria | on | Order | Secondary Sort Order |
| Name | pr_title | Alphabetical, | sc_air_date (Air Date) |
| Title | | ascending | |
| Program | | | |
| Show | | | |
| Showname | | | |
| Time | sc_air_date | Chronological, | st_tms_chan (Channel |
| Date | | | Number) |
| Showtime | | | |
| Number | st_tms_chan | Numerical, | sc_air_date (Air Date) |
| Channel | | ascending | |
| Channel | st_name | Alphabetical, | sc_air_date (Air Date) |
| Name | | ascending | |

5. $Time

Valid dates, times, time ranges, time spans and time points may be specified in a variety of ways in various embodiments. For example, a date may be specified as a day of week (e.g., “Monday”), as a month and a day (e.g., “January 2^{nd} or “the 3^{rd} day of March”), as a day of year (e.g., “January 12^{th} 2007” or “day 12 of 2007”), etc., and may be specified relative to a current date (e.g., “this” week, “next” week, “last” month, “tomorrow”, “yesterday”, etc.) or instead in an absolute manner. Time-related information may similarly be specified in various ways, including in an absolute or relative manner, and such as with a specific hour, an hour and minute(s), a time of day (e.g., “morning” or “evening”), etc. Furthermore, in at least some such embodiments at least some of such terms may be configurable, such as to allow “morning” to mean 7 am-2 pm or instead 6 am-noon. In addition, in at least some embodiments various third-party software may be used to assist with some or all speech recognition performed, such as by using VoiceBox software from VoiceBox Technologies, Inc. Further, in at least some embodiments, if time is not provided, it is left blank so that the STB/DVR can use the last time requested by user.

6. $Title

Fields to Search for $Title:

Pr_title

7. $VirtualButton

We will use this example list.

Spoken Criteria

Cancel | Cancel Changes
Change
Close
Delete
Get this episode only | This episode only |
Episode only
Keep 2 days | Keep two days | 2 days | Two days
Keep Until | Until
No, Close | No
Play
Record Once | Once
Record Series | Series
Recording Options
Save
Start on Time | Start Recording on Time
Stop on Time | Stop Recording on Time
Stop Recording
View upcoming | Upcoming
Watch

D. Identifying a Program

1. Program Identification

Programs Can be Identified by Four Fields:

pr_id (Program ID)
st_id (Station ID)
sc_air_date (Air Date)
st_tms_chan (Channel Number)
   E. Example Command Recognition, Feedback and Errors

1. Error Handling/User Feedback

Errors will be handled by the STB/DVR. If the user issues an invalid command that is not handled in a current UI state or modal dialog using voice command or remote control, the STB/DVR will play a “bonk” audio alert. For example, if the user asks an illegal navigation command while in the STB/DVR guide or the user utters “record” while watching a recorded program, the STB/DVR will either do nothing or play “bonk”.

2. Audio Input Level

The STB/DVR UI will display the audio input volume, and the application will call an appropriate API and provide the volume level (1-10) if the volume level is changed.

3. Recognized Flag

When a command is recognized, the application will call an appropriate API with the recognized (or “reco”) flag, an appropriate API with the spoken text string uttered by the user and the appropriate command API. The STB device being controlled will perform the desired action; visual and audio feedback to the user is handled by the device UI. 4. Not Recognized Flag

When a command is not recognized, the application will call an appropriate API with a not recognized flag and call an appropriate API with the spoken text string uttered by the user. Displaying a not recognized status in the UI and the spoken utterance will be handled by the STB device.

F. Using Search Commands

The default join between additional search criteria in this example embodiment is an “AND”, so as to further narrow the list. For example, if the end user says “Find shows starring Tom Hanks”, and then says “Which ones star Meg Ryan”, then a list would be returned with shows that have BOTH Tom Hanks AND Meg Ryan listed as actors. However, there are a few instances where criteria is instead swapped rather than joined.

1. Criteria Swapping

There are a few types of criteria where we swap one value for another. This is instead of using an “OR” for these few cases, which could instead by used in other embodiments.
Channel
Date/Time
Is repeat/Is not a repeat
   Examples:
Find shows called Friends. Which are on channel 13? Which are on NBC?
Find baseball games on tonight. Which are on at 8?
Find shows called the Apprentice. Which ones are repeats? Which are not repeats?

2. Search Results

a. Success Search with Results

On successful search commands, the application will call an appropriate API with the recognized flag and call an appropriate API along with the search criteria and the result set.

b. Search with No Results

This cases will handled as above except the results will be empty. The application will call an appropriate API with the recognized flag and call an appropriate API along with the search criteria and empty result set.

c. Unrecognized Criteria (“Find Shows Starring Gobbledygook”)

If the command partially recognized where the criteria is not recognized, the application will call an appropriate API with a recognized flag along with the utterance text and call an appropriate API with the criteria type and empty value for the criteria. The result set will be the same as the previous search.

d. Sort or Sub-Search While no Search in Progress

If the user attempts to perform a sort or a sub-search while no search is in progress, the command will be treated an invalid command. The application calls an appropriate API with recognized flag and call an appropriate API with heard utterance and call an appropriate API with empty criteria and result set.

G. Example UI

There are three major UI components in this example embodiment. First is the feedback mechanism which indicates to the end user that the system is listening for a command, what it heard, and if it understood. Second is the search results interface which displays the criteria and result set for the current search, as well as detailed program information and actions that can be taken on the programs. Last is the help interface which will describe the basic commands and functions of the speech interface.

1. Feedback

Feedback comes in multiple forms in this example embodiment. First is the presence of a Feedback Bug—a UI element that provides visual feedback to the end user, second is audio feedback that accompanies the Feedback Bug with a success or failure sound, and third is response of the system by executing the request of the end user. This section covers the first two methods of feedback.

a. UI Elements & Placement

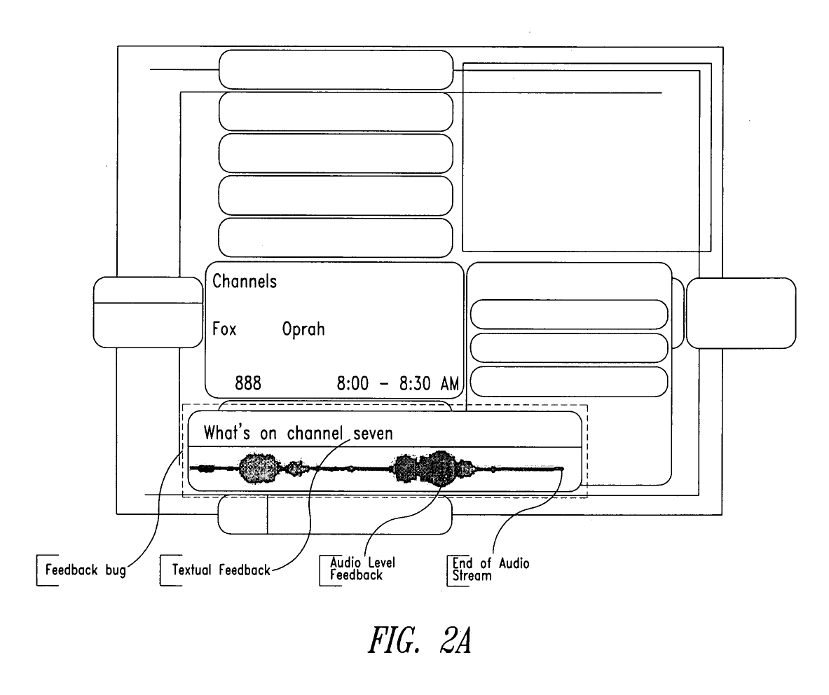

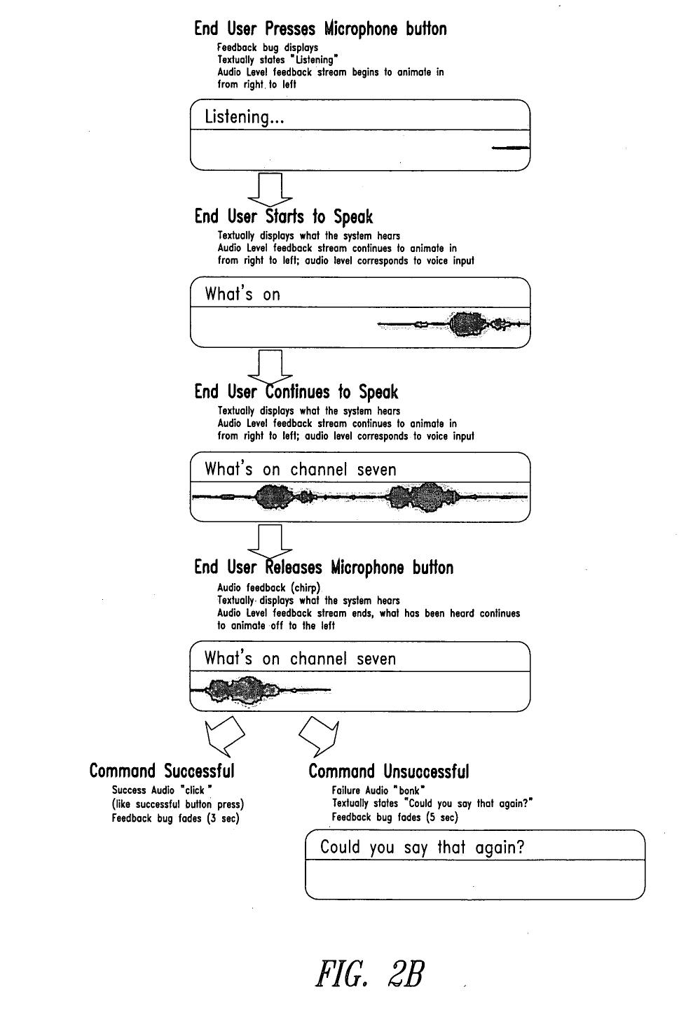

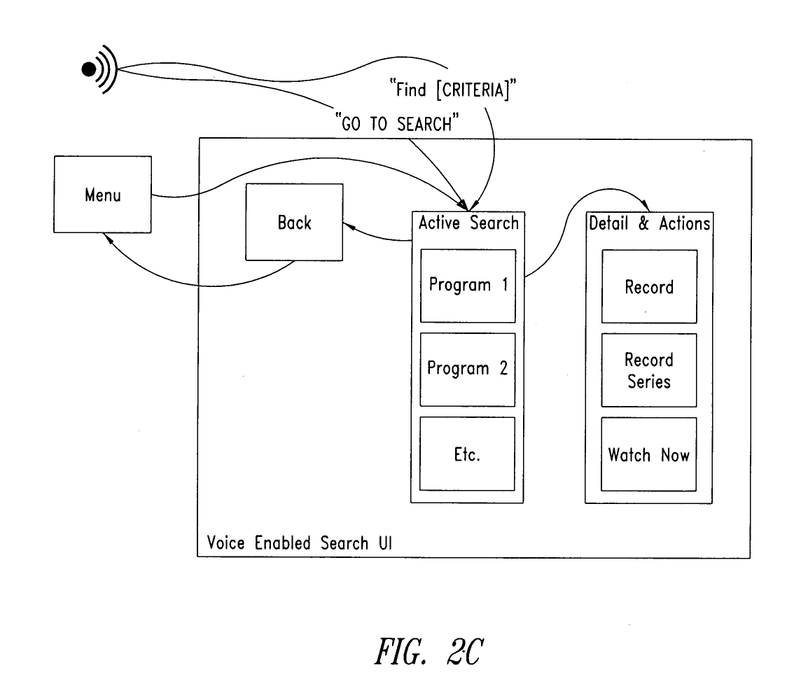

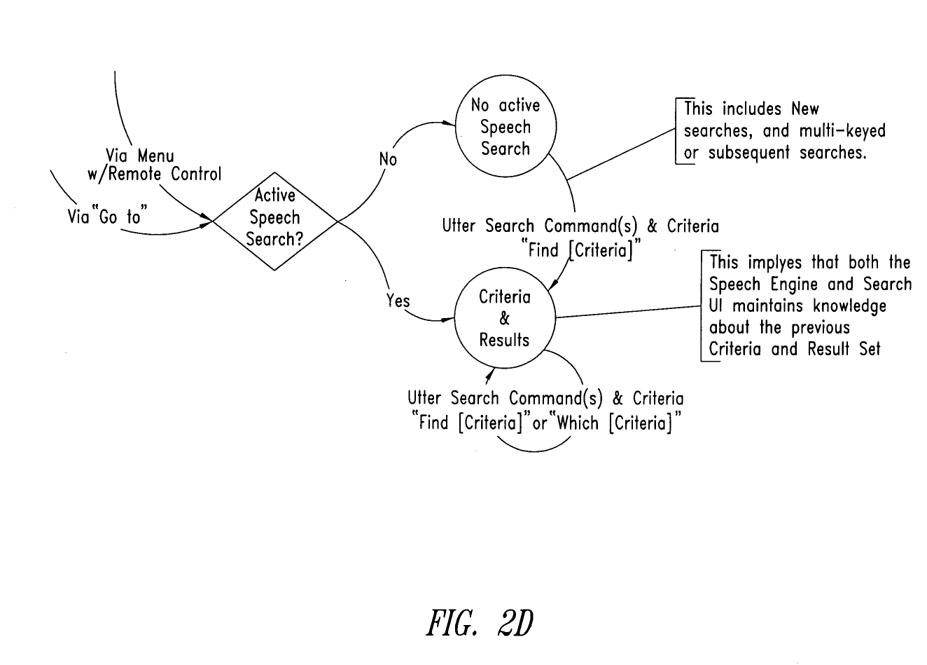

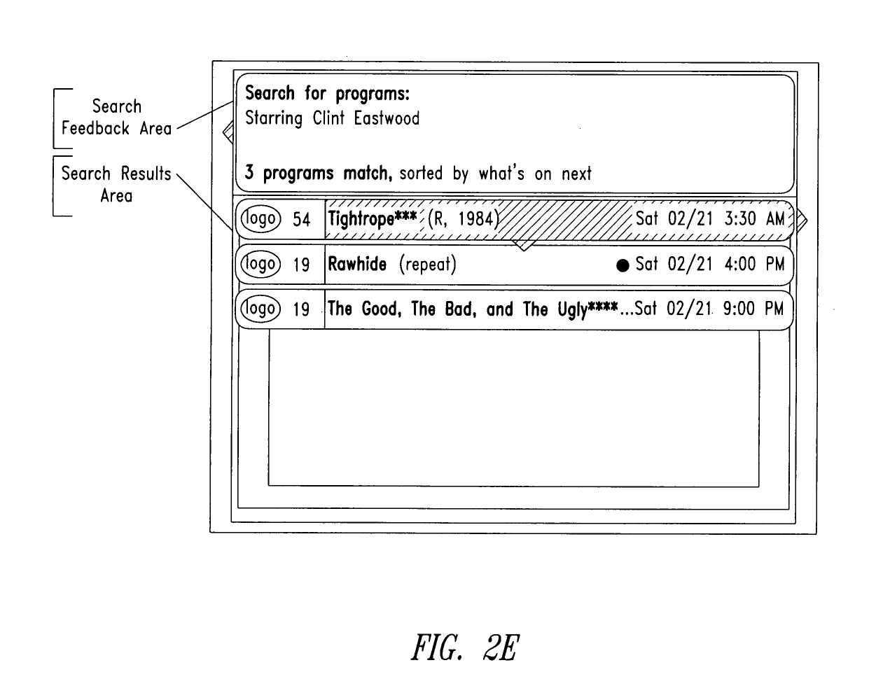

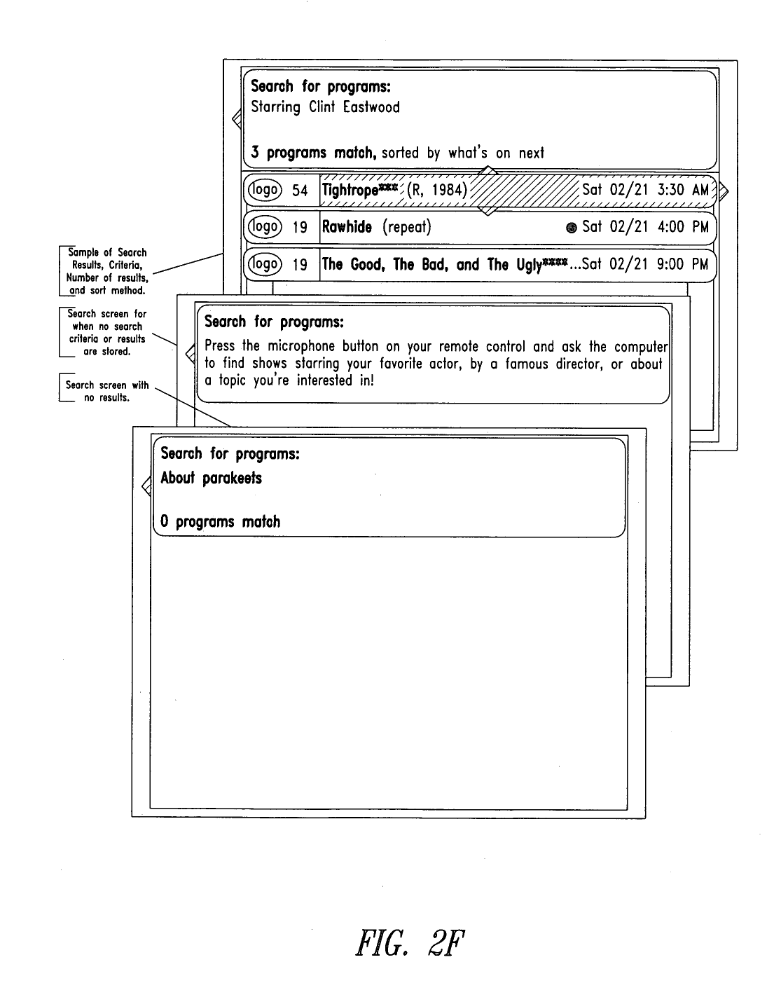

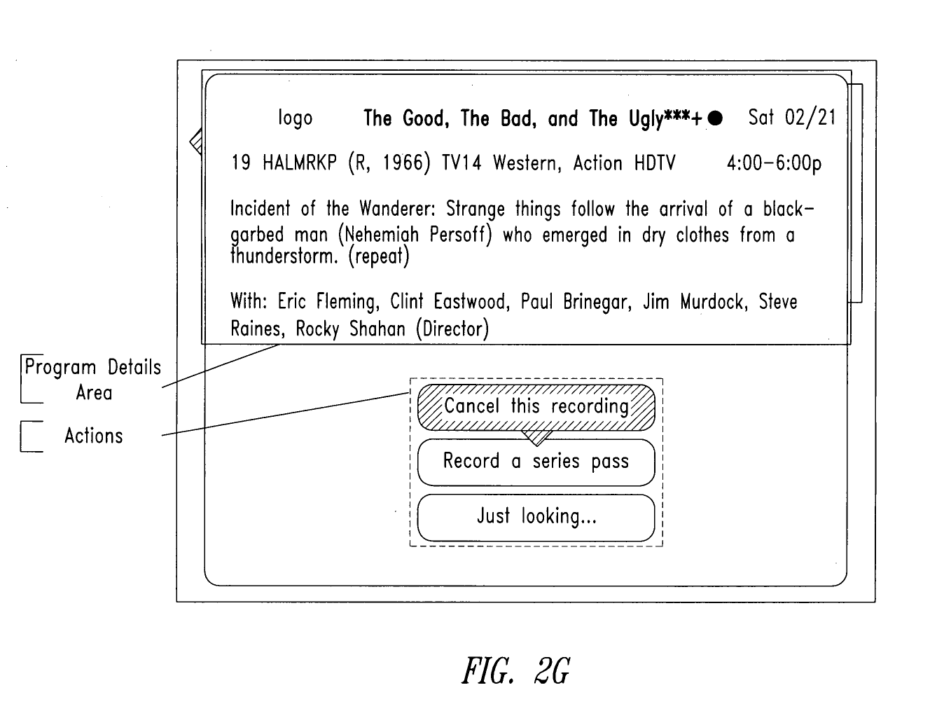

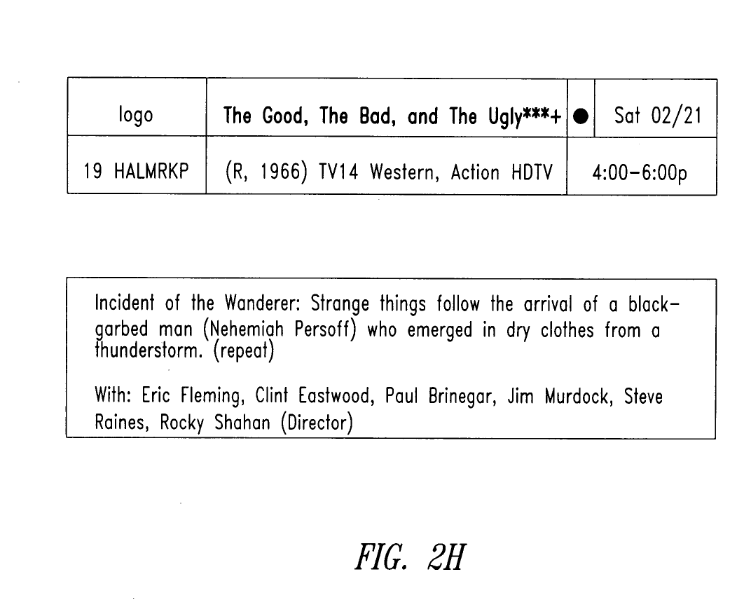

The Feedback “bug” displays in the lower portion of the screen in this example embodiment, and is horizontal in nature to accommodate both the text and audio level feedback that will display. FIG. 2A illustrates an example of a UI with a Feedback bug.

b. Functions and States

As an end user interacts with the microphone, speaks, releases the microphone button and observes the results, the Feedback Bug adapts. FIG. 2B illustrates an example of such adaptation.

2. Search

Because searches that can be executed with voice commands may have additional levels of feedback and use a different interface for submitting the criteria, a new interface is used.

a. Structure

There are three entry points to the search UI in this example embodiment: first, using the remote control and accessing it from the STB/DVR menu, second, using the “Find” voice command and including criteria, and third, using the “Go To” voice command with Search as the destination. FIG. 2C illustrates an example of such search.

b. States

There are two basic states to the search in the example embodiment, with either an active search with criteria and results in memory, or no active search when there aren't any criteria and results in memory. This affects two of the entry points: going to the Search via the STB/DVR menu with the remote control, and going to the Search via the “Go to” voice command. Both arrive at the search interface without providing new criteria. Upon arrival, they will see one of two versions of the search results screen: one that will display if there are no criteria or results in memory that includes some basic help text or one that will display the active search criteria and results, even if the last search generated no results. FIG. 2D illustrates an example of this process.

c. Passing, Retrieving, Saving, and Updating Search Data

The Search UI may receive criteria, results, and possibly a sort order via the API. Criteria consist of the criteria types and values. Data to be passed about each result is described in the Search Results Screen section. The Search UI may also receive a sort order. Additional data about each result (used for detailed display of an individual result) will be requested by the Search UI using the identifying fields described in the Identifying a Program section. The Search UI stores the sort order and applies it when searches update, but flushes it with new searches (and use the default instead). This means that each search is identified as either a new search or an update to the current search.

d. Search Results Screen

There are three versions of the search screen in this example embodiment.

The first is for when there are criteria and results in memory, the second is for when there are criteria and no results in memory, and the third is for when there are neither criteria nor results in memory. Each version of the Search Results Screen has a header area that provides feedback about the search criteria, results, and the sort order. Below the header is the result list, if there are indeed results to display. FIG. 2E illustrates an example of the search screen.

i. Search Feedback Area

The Search Feedback Area displays information slightly differently in this example embodiment based on thee different states: Active Search with results, Active Search without results, and No Active Search (and therefore no results). FIG. 2F illustrates an example of the feedback area.

(1) Active Search with Results

When a search has both criteria and results, the feedback area displays the following elements: enumeration of the criteria, the number of matches, and the sort order.

(2) Active Search with No Results

When a search returns no results, the feedback area displays the following elements: enumeration of the criteria and the number of matches—which will be zero (0). The sort order will not display as it is not relevant.

(3) No Active Search

When there are no criteria stored (and therefore no results), help text displays in place of criteria. The number of matches and sort order are not displayed as they are not relevant. An example of such help text is as follows:

“Press the microphone button on your remote control and ask the
computer to find shows starring your favorite actor, by a famous director,
or about a topic you're interested in!”

(b) Search Criteria

The search criteria may be grouped by type and listed in the following order, with the following qualifiers (except for Genre, Time, and Attribute):
$Genre
Called $Title
Starring $Actor
Directed by $Director
About $Keyword
On Channel $ChannelNumber—$ChannelName
$Time
$Attribute

(1) Rules for Displaying Time Criteria

Time may be displayed as a single point in time or a range, and may follow this format:
Single point in time: Tues 2/3 6:00 pm
Range of time (E.g. “evening”): Tues 2/3 6:00-9:00 pm
Range of time overlapping days (E.g. “latenight”): Tues 2/3 11:00 pm-5:00 am (thus displaying the name of the day that corresponds to the start time)

(2) Rules for Displaying Multiple Criteria of a Single Type

Multiple of the same criteria type may be dealt with as follows:
Two: Criteria A and Criteria B
Three or more: Criteria A, Criteria B, and Criteria C

(3) Rules for Case

The display of criteria appears in sentence case in this example embodiment, and values for each criteria type may appear as they are stored.

Examples:

Comedy, starring Tom Hanks and Meg Ryan, about Seattle
Baseball, on ESPN, HDTV
Called Friends, on NBC, about Phoebe and wedding

(c) Number of Matches

This is the number of matches followed by the text “programs match”, unless the number is zero (0), in which case it should be followed by the text “program matches”. The number can be zero.

(d) Sort Order

The sort order displays if there are results greater than zero. The default sort order is by Title. For secondary sorts, please see the $Sort section. Here is an example of what to display for each sort order:

| Sort Order | Display Text |
|---|---|
| Title | , sorted by show title |
| AirDate | , sorted by show time |
| ChannelNumber | , sorted by channel number |
| ChannelName | , sorted by channel name |

ii. Search Results Area

Results are listed below the feedback area.

(a) Selections and Status

If there are one or more results, then one will be selected. If the end user moves away from the Search Results Screen but stays within the Speech Search application and then returns to the Search Results Screen, the selected result will still be selected. For example, if the end user moves the selection to the second result on the list, and then goes to the Detail and Actions Screen for that result, and then comes back to the list of results, the second result will still be selected.

(b) Data

Each result should include the following (if available—movies won't be repeats and episodes won't display star, release year or MPAA ratings):

| Field | Purpose |
|---|---|
| Channel Logo (via st_id (Station ID)) | Display, uniquely identifying the |
| | program |
| st_tms_chan (Channel Number) | Display, uniquely identifying the |
| | program |
| st_name (Channel Name) | Display (to get the logo) |
| pr_id (Program ID) | Uniquely identifying the |
| | program |
| pr_title (Program Title) | Display |
| pr_star_rating (Star Rating) | Display |
| pr_mpaa_rating (MPAA Rating) | Display |
| pr_year (Year) | Display |
| sc_flags:tf_repeat (Repeat) | Display |
| Recording Status (if enumerated | Display |
| recording schedules/lists are available) | |
| sc_air_date (Air Date) | Display, uniquely identifying the |
| | program |

(c) List

The first item in the list displays at the top of the list, just below the Feedback Area. When a new result set displays, the first item in the list may also be selected, appearing visually distinct from the rest of the result set.

e. Detail and Actions Screen

The Detail and Actions Screen displays detailed program information about the selected result as well as all the actions that can be taken on that program.

i. UI Elements & Placement

There are two regions of the Detail and Actions Screen in this example embodiment: the area dedicated to program Details and the list of Actions. FIG. 2G illustrates an example of general placement information for this screen, while FIG. 2H provides information about example layout information, and the following provides information about example field information.

| | | | |
|---|---|---|---|
| st_id | pr_title | rc_status | sc_air_date |
| | pr_star_rating | rq_status | |
| st_tms_chan | pr_mpaa_rating | | sc_air_date |
| st_call_sign | pr_year | | sc_duration |
| | pr_advisory_1 | | |
| | ge_genre | | |
| | sc_flags:tf_hdTV | | |
| Pr_epi_title | | | |
| Pr_desc_0 | | | |
| Sc_flags:tf_repeat | | | |
| Cc_first | | | |
| Cc_last | | | |
| Cc_role | | | |

(1) Displaying Program Details
Start time—end time
Genres
Cast/Crew

(b) Actions

The following actions are available in the following order for the following states of a program, and will be listed in the following order (top to bottom) with the first item as the default selection:

| | | | | | Future, | |
|---|---|---|---|---|---|---|
| | Pre- | On Now, | On | Future, | Sched- | Future, |
| | viously | Not | Now, | Un- | uled | Sched- |
| | Record- | Record- | Record- | sched- | Prog- | uled as |
| Action | ed | ing | ing | uled | ram | Series |
| Watch this | | ✓ | ✓ | | | |
| program | | | | | | |
| Play this | ✓ | | | | | |
| recording | | | | | | |
| Record this | | ✓ | | ✓ | | |
| program | | | | | | |
| Record a | | ✓ | | ✓ | ✓ | |
| series pass | | | | | | |
| Cancel this | | | ✓ | | ✓ | ✓ |
| recording | | | | | | |
| Delete this | ✓ | | | | | |
| recording | | | | | | |
| Just Looking | ✓ | ✓ | ✓ | ✓ | ✓ | ✓ |
| . . . | | | | | | |

f. Navigation and Interaction

The end user can use the remote control's directional arrows and OK button to navigate and select items on the screen. On-screen arrows indicate which directional arrows can be used at any given time. Other remote control buttons also have functionality.

i. On-screen Navigation Elements

(a) Up/Down Arrows

(1) Context

Up and Down arrows may appear above and below a selected item in a list.

The on-screen Up and Down arrows indicate that the Up and Down arrows on the remote control can be used.

(2) Display Rules
IF there is ≦1 item in the list:
   Neither up nor down arrows will display.
IF there are ≧2 items in the list:
   Only a down arrow will display on the top result
   Only an up arrow will display on the bottom result
   Both up and down arrows will display on any result in between

(b) Left Arrow

Context

The Left arrow is displayed and is visually attached to the selected result.

(c) Right Arrow

The right arrow displays to the right of the selected result. If there are no results, the right arrow will not display.

ii. Remote Control Interaction

The remote control buttons which may have functionality include:
Up Arrow
Down Arrow
Left Arrow
Right Arrow
OK button
Info Button
Channel Up
Channel Down
Record
Play
Clear

(a) Up/Down Arrow buttons

(1) Context

The Up and Down arrows move the selection up and down through items in a vertical list.

(2) Functionality

If there are no results or one item in the list, then pressing either the Up and Down arrow will result in a ‘bonk’. When the complete list is visible on-screen, the result set is static, and the selection moves up and down within the visible list. When a list extends past the bottom (or top) of the screen, the selection can be moved down to the last visible item. With each successive down arrow button press the list is raised one item at a time so that the next item in the list is visibly selected. When the end user reaches the last item in the list, the first down arrow button press yields nothing, but a successive press brings the selection to the first item in the list, although the first item on the list is at the top of the page now, followed by the second, etc. Similarly, if the end user presses the up arrow on the first item in the list, the first press yields nothing, but the second selects the last item, although that selection is now at the bottom of the page. This means that the top and the bottom of the list do not appear beside each other—the end user is in one place in a linear, non-circular list.

(b) Left Arrow button

The Left arrow button brings the ‘Back’ button from the left into focus, shifting the search results to the right.

(c) Right Arrow,

(d) OK Button

Both the OK and Right arrow buttons bring the Detail and Actions Screen with information about he selected result into view from the right.

(e) Channel Up/Down (Page Up/Down) Buttons

(1) Context

The Channel Up/Down buttons act as Page Up/Down buttons when presented with a list. Page Up/Down functionality is available when the list extends past the visible edge screen, so as to bring up a new “page” worth of items.

(2) Functionality

When possible, do the following:
Leave the selection in the same place on the screen.
For Page Down the item that is last on the page moves to the top of the page when possible and is therefore still visible, providing some overlap between button presses.
For Page Up the item that is first on the page moves to the bottom of the page when possible.
If there is less than one screen's worth of items in the list to display (going up or down) then display to the start or end of the list.
If at the bottom or top of the screen, it should work the same as the Up/Down arrow buttons—bonking the first time, and then moving to the other end of the list.

(f) Info Button

The Info button should be active when there is a program selected.

(1) Functionality

It should perform the default Info action—to bring up the Program Info tone with information about that program.

(g) Record Button

(1) Context

The Record button should be active when there is a program selected.

(2) Functionality

It should perform the default Record action—to bring up the applicable recording actions for the selected program.

(h) Play Button

(1) Context

This may not be used if we are not including recorded (or currently recording) programs in the result set. The Play button should be active when there is a recorded program selected.

(2) Functionality

It should perform the default play action—to play the recorded program full screen.

(i) Clear button

(1) Context

This may not be used if we are not including recorded (or currently recording) programs in the result set. The Clear button should be active when there is a recorded program selected.

(2) Functionality

It should perform the default Clear action—to initiate a delete action which will bring up the delete confirmation note.

3. Help
Basic Commands
Searching for programs
Tips
   H. Temp Holding Area

1. Program Information

When passing program information to the Search UI for display, the following fields may be included:

i. Channel Information:
st_tms_chan
st_name

ii. Program Information:
pr_title
pr_desc_{—}0
pr_year
pr_mpaa_rating
pr_star_rating
pr_run_time
pr_epi_title

iii. Cast/Crew Information:

For Those Where the Value for cc_Role is Actor or Director

cc_first
cc_last
cc_role

iv. Genre Information:
ge_genre

v. Schedule Information:
sc_air_date
sc_end_date
sc_flags
   tf_repeat
   tf_hdTV

2. Other

The Search UI stores the criteria, results, and sort order to allow end users to go to their most recent search.
Enhanced Program Info Rather than just bring up program info about a program in focus, Find the program AND bring up the program info in one step
   E.g.—“Who's on David Letterman tonight?”
   E.g.—“What's NOVA about tonight?”
Game Search Find games and show who's playing.
   E.g.—“Who's playing tonight?”
   E.g.—“When are the Sonics playing next?”

a. Error Recovery

This feature uses two things: first, a log of the viewer's commands and contexts, and second, a way to ‘back out’ of any of those commands. This can be involved if the viewer has just scheduled a series pass and the scheduler has just run, if the viewer has just deleted a recording, or if the viewer has just changed the channel and the buffer has been flushed. This includes:
Going back to the last place they were in the STB/DVR Menu
Going back to the last channel tuned (use the “Jump” command) (the buffer will be flushed)
Dismissing a note (use the action that the note would use in a time-out situation, not the default action).

i. Commands

| Voice Command | Result |
|---|---|
| Oops | Reverses the last action taken |

ii. Errors

If the viewer tries to use this command where inappropriate, bonk!

3. Positive Feedback

There are two forms of positive feedback already offered by this example embodiment of the system: audio and visual. First, there is a sound effect that provides positive feedback—a ‘bink’ instead of the negative ‘bonk’. Second, the viewer sees the interface move and/or change as it implements the command. However, some of the voice commands take viewers to and from places in the STB/DVR menu and other applications with few steps, and thus possibly little feedback. For example, if a viewer is watching a live show full-screen, and then issues the Voice Command “What's on at seven?”, the screen could immediately be redrawn, or instead the STB/DVR menu may come up with the current show in center focus and then have the vertical axis advance to seven o'clock. Another type of positive feedback that the system can provide on-screen to communicate to the viewer that it's ‘listening’ to their voice commands is in the form of an indicator that appears, such as when the viewer depresses a microphone button on the remote control. This indicator may be placed in the bottom left-hand corner of the screen, and it contains relevant iconography (e.g., a microphone).

4. Errors

Errors focus on educating the viewer, and may be kept low in number and complexity. This should enhance the ‘learnability’ of the voice command system. Errors, like the rest of the system, may depend on the context where the command was uttered. They also depend on how much of the command the system ‘hears’ and understands.

All error notes include body text and an OK button. Some may include multiple pages of information, and use the standard note template to handle this with its ‘back’ and ‘ahead’ buttons.

| | |
|---|---|
| Title Text | Body Text |

i. Unknown Command Error

| | |
|---|---|
| Unknown Voice | We could not find a matching voice command. |
| Command | Here are some tips: |
| | Use the microphone to ask “What's on” a |
| | channel or time. |
| | Tell device to “Find a show called .” |
| | Get there quick by telling device to “Go to my |
| | Photos.” |

ii. Unknown Time Error

| | |
|---|---|
| What timeframe would | We could not find a matching time. |
| you like to look at? | Try asking “What's on at 7 pm?” or “What's |
| | on tomorrow at 4:30?” |

iii. Find Error

| | |
|---|---|
| Can we help you find | We could not find a matching search. |
| something? | Try asking device to “Find a show about” |
| | something, or to “Find a show starring” |
| | someone. |

iv. Go Where? Error

| | |
|---|---|
| Where would you like | We could not find a matching destination. |
| to go? | Try asking device to “Go to Photos” to view |
| | your albums, “Go to the beginning” of what |
| | you've recorded, or even “Go to Channel |
| | four” full screen. |

While not illustrated, in some embodiments a variety of other types of content can similarly be reviewed, manipulated, and controlled via the described techniques. For example, a user may be able to manipulate music content, photos, video, videogames, videophone, etc. A variety of other types of content could similarly be available. In a similar manner, but while not illustrated here, in some embodiments the described techniques could be used to control a variety of devices, such as one or more STBs, one or more DVRs, one or more TVs, one or more of a variety of types of non-TV content presentation devices (e.g., speakers), etc. Thus, in at least some such embodiments, the described techniques could be used to concurrently play a first specified program on a first TV, play a second specified program on a second TV, play first specified music content on a first set of one or more speakers, play second specified music content on a second set of one or more speakers, present photos or video on a computing system display or other TV, etc. When multiple such devices are being controlled, they could further be grouped and organized in a variety of ways, such as by location and/or by type of device (or type of content that can be presented on the device). In addition, voice commands may in some embodiments be processed based on a current context (e.g., the device that is currently being controlled and/or content that is currently selected and/or a current user), while in other embodiments the voice commands may instead be processed in a uniform manner. In addition, extended controls of a variety of types beyond those discussed in the example embodiment could additionally be provided via the described techniques in at least some embodiments.

In addition, in some embodiments multiple pieces of content can be simultaneously selected and acted on in various ways, such as to schedule multiple selected TV programs to be recorded or deleted, to group the pieces of content together for future manipulation, etc. Moreover, in some embodiments multiple users may interact with the same copy of an application providing the described techniques, and if so various user-specific information (e.g., preferences, custom filters, prior searches, prior recordings or viewings of programs, information for user-specific recommendations, etc.) may be stored and used to personalize the application and its information and functionality for specific users. A variety of other types of related functionality could similarly be added. Thus, the previously described techniques provide a variety of types of content information and content manipulation functionality, such as based on voice controls.

In some embodiments the functionality provided by the routines discussed above may be provided in alternative ways, such as being split among more routines or consolidated into fewer routines. Similarly, in some embodiments illustrated routines may provide more or less functionality than is described, such as when other illustrated routines instead lack or include such functionality respectively, or when the amount of functionality that is provided is altered. In addition, while various operations may be illustrated as being performed in a particular manner (e.g., in serial or in parallel, or synchronous or asynchronous) and/or in a particular order, in other embodiments the operations may be performed in other orders and in other manners. The data structures discussed above may also be structured in different manners, such as by having a single data structure split into multiple data structures or by having multiple data structures consolidated into a single data structure. Similarly, in some embodiments illustrated data structures may store more or less information than is described, such as when other illustrated data structures instead lack or include such information respectively, or when the amount or types of information that is stored is altered.

From the foregoing it will be appreciated that, although specific embodiments of the invention have been described herein for purposes of illustration, various modifications may be made without deviating from the spirit and scope of the invention—for example, the described techniques are applicable to architectures other than a set-top box architecture or architectures based upon the MOXI™ system. Accordingly, the invention is not limited except as by the appended claims and the elements recited therein. The methods and systems discussed herein are applicable to differing protocols, communication media (optical, wireless, cable, etc.) and devices (such as wireless handsets, electronic organizers, personal digital assistants, portable email machines, game machines, pagers, navigation devices such as GPS receivers, etc.) as they become broadcast and streamed content enable and can record such content. Accordingly, the invention is not limited by the details described herein. In addition, while certain aspects of the invention have been discussed and/or are presented below in certain claim forms, the inventors contemplate the various aspects of the invention in any available claim form, including methods, systems, computer-readable mediums on which are stored executable instructions or other contents to cause a method to be performed and/or on which are stored one or more data structures, computer-readable generated data signals transmitted over a transmission medium and on which such executable instructions and/or data structures have been encoded, etc. For example, while only some aspects of the invention may currently be recited as being embodied in a computer-readable medium, other aspects may likewise be so embodied.

What is claimed is:

1. A method for controlling presentation of a plurality of types of content using voice commands, the method comprising:
at a computing device in a home environment that controls presentation of content, receiving a plurality of pieces of content of a plurality of types from at least one content server system and receiving metadata information about the received pieces of content, the plurality of types of content including at least one of audio content, image content, and video content; and
under control of the computing device,
receiving a voice command from a user of the computing device that contains one or more criteria for selecting one or more pieces of content to be controlled and that contains an instruction related to a type of control;
analyzing the voice command to identify the instruction and the one or more criteria;
using the metadata information to identify one or more of the received pieces of content that correspond to the identified one or more criteria; and
performing the identified instruction on at least one of the identified pieces of content.

2. The method of claim 1 wherein the received voice command further contains an indication of a type of content, wherein the analyzing includes identifying the indicated type of content, and wherein the method further comprises determining a presentation device associated with the identified type of content.

3. The method of claim 2 wherein the performing of the identified instruction on the at least one identified piece of content includes sending the identified instruction to the determined presentation device for use in controlling presentation of the at least one identified piece of content.

4. The method of claim 1 wherein the computing device is one of a digital video recorder (“DVR”) device, a set-top box device and a media center device, wherein the user is a current one of a plurality of users of the computing device, wherein the current user is at a first location in the home environment and wherein the computing device is located at a second distinct location in the home environment, wherein the current user provides the voice command to a remote control device that is located with the current user at the first location, wherein the receiving of the voice command by the computing device is in response to transmitting of the voice command by the remote control device, wherein the analyzing of the voice command includes performing speech recognition in a manner specific to the current user and uses current state information for the computing device and is performed so as to identify one or more words for the instruction and one or more words for the criteria, wherein the one or more words for the criteria include one or more descriptive words, wherein the instruction is to search for one or more corresponding pieces of content that satisfy the criteria by matching those descriptive words, wherein the identifying of the one or more received pieces of content by using the metadata information includes performing the search, and wherein the performing of the identified instruction on at least one of the identified pieces of content includes presenting information to the current user that indicates the one or more identified pieces of content.

5. The method of claim 4 wherein the presenting to the current user of the information that indicates the one or more identified pieces of content includes transmitting the information to a display device in the home environment, and including receiving an additional voice command from a user that selects one of the identified pieces of content and in response presenting the one identified piece of content.

6. The method of claim 1 wherein the computing device is a digital video recorder (“DVR”) device, wherein the at least one identified piece of content is streamed or broadcasted content that will be received at a future time, wherein the identified instruction indicates to perform a recording, and wherein the performing of the identified instruction by the DVR device includes recording the at least one identified piece of content at the future time.

7. The method of claim 1 wherein the computing device is a media center device, wherein the user is local to the set-top box device in the home environment, wherein the at least one identified piece of content includes audio information that is currently available for presentation, and wherein the performing of the identified instruction by the media center device includes initiating current presentation of the at least one identified piece of content to the user on at least one audio presentation device in the home environment.

8. The method of claim 1 further comprising, before the performing of the identified instruction on the at least one identified piece of content, displaying feedback to the user that indicates the instruction and the criteria that are identified from the analyzing of the voice command and modifying at least one of the instruction and the criteria based on additional information received from the user.

9. The method of claim 1 further comprising receiving one or more voice annotations from the user, each of the voice annotations providing descriptive information related to a piece of content, and initiating storage of each of the voice annotations in a manner associated with the piece of content for the voice annotation.

10. The method of claim 1 wherein the computing device receives the voice command from a remote control device to which the user had provided the voice command, and wherein the analyzing of the voice command includes identifying one or more words for the instruction and determining the identified instruction by mapping the identified words to one of a plurality of predefined instructions that are supported by the computing device and/or by an associated presentation device in such a manner that the remote control device can transmit signals to the computing device and/or the associated presentation device that correspond to the predefined instructions based on manual operation by the user of one or more controls on the remote control device.

11. The method of claim 1 wherein the received pieces of content include music recordings, non-music audio recordings, images, and video recordings, wherein the received pieces of content include streamed content and non-streamed content, and wherein the performing of the identified instruction on the at least one identified piece of content includes sending the identified instruction and/or the at least one identified piece of content to at least one presentation device, the at least one presentation devices comprising one or more speaker devices, music player devices, gaming devices, image display devices, cellphone devices, Internet appliance devices, cameras, videophones, and general purpose computing devices.

12. A computer-readable medium whose contents enable a computing device to manage content based on voice-based control instructions, by performing a method comprising:
receiving metadata information for a plurality of pieces of content;
receiving one or more voice-based control instructions generated by a user that relate to a type of control of at least one of the pieces of content;
identifying one or more actions to be performed regarding one or more of the pieces of content, the identifying based at least in part on the received voice-based control instructions and based at least in part on the received metadata information; and
performing the identified one or more actions regarding the one or more pieces of content, so as to manage presentation of content on one or more presentation devices local to the computing device.

13. The computer-readable medium of claim 12 wherein the plurality of pieces of content are of a plurality of types, wherein the method further comprises:
identifying at least one type of content to which the received control instructions relate;
identifying the one or more pieces of content based at least in part on the identified at least one type of content; and
determining a presentation device associated with the identified at least one type of content,
and wherein the performing of the identified one or more actions regarding the one or more pieces of content includes forwarding information to the determined presentation device to cause performance of the identified one or more actions regarding the identified pieces of content.

14. The computer-readable medium of claim 12 wherein the computing device is one or more of a digital video recorder (“DVR”) device, a set-top box device, and a media center device, and wherein the presentation device is one or more digital video recorder (“DVR”) devices, set-top box devices, media center devices, speakers, music players, gaming device, image display devices, cameras, videophones, Internet appliance devices, cellular telephones, or general purpose computing devices.

15. The computer-readable medium of claim 12 wherein the computer-readable medium is a memory of the computing device and/or is a data transmission medium transmitting to the computing device a generated data signal containing the contents.

16. The computer-readable medium of claim 12 wherein the contents are instructions that when executed cause the computing device to perform the method.

17. A computing device configured to manage a plurality of types of non-television content based on voice commands, comprising:
at least one input mechanism able to receive one or more voice commands generated by a user that relate to a type of control of one or more of a plurality of types of content; and
a voice command processing system configured to analyze the received voice commands to identify one or more actions to be performed regarding one or more pieces of content of at least one of the plurality of types based at least in part on metadata information about those pieces of content and to initiate performance of the identified one or more actions regarding the one or more items of content.

18. The computing device of claim 17 wherein the at least one input mechanism includes one or more of a microphone, a network interface connection, a direct physical connection from one or more other devices, and a connection to allow wireless communication from one or more other devices.

19. The computing device of claim 17 wherein the voice command processing system includes software executing in memory of the computing device.

20. The computing device of claim 17 wherein the voice command processing system consists of a means for analyzing the received voice commands to identify one or more actions to be performed regarding one or more pieces of content of at least one of the plurality of types based at least in part on metadata information about those pieces of content and for initiating performance of the identified one or more actions regarding the one or more items of content.
